(19) United States
(12) Patent Application Publication
(10) Pub. No.: US 2015/0289399 A1
(43) Pub. Date: Oct. 8, 2015

(54) HOUSING ASSEMBLY

(71) Applicants: LITE-ON ELECTRONICS (GUANGZHOU) LIMITED, GUANGZHOU (CN); LITE-ON TECHNOLOGY CORPORATION, TAIPEI CITY (TW)

(72) Inventor: JUI-CHI LIAO, NEW TAIPEI CITY (TW)

(73) Assignees: LITE-ON ELECTRONICS (GUANGZHOU) LIMITED, GUANGZHOU (CN); LITE-ON TECHNOLOGY CORPORATION, TAIPEI CITY (TW)

(21) Appl. No.: 14/290,943

(22) Filed: May 29, 2014

(30) Foreign Application Priority Data
Apr. 2, 2014 (CN) 201410131574.2

(51) Int. Cl. H05K 5/02; H05K 5/03; H05K 7/14; H05K 5/00

(52) U.S. Cl. CPC H05K 5/0217; H05K 5/0008; H05K 5/03; H05K 7/1417

(57) ABSTRACT

A housing assembly includes a first housing, a second housing, two first bolts, two second bolts, two first guiding rails and two second guiding rails. The first housing has a top board and two side boards. The second housing has a bottom board. The two first bolts and two second bolts are formed on the two side boards of the first housing. The two first guiding rails and two second guiding rails are formed on two sides of the bottom board of the second housing. Each first guiding rail has a first guiding groove, which includes a first vertical section, a first horizontal section, a first opening and a first fixing node. Each second guiding rail has a second guiding groove, which includes a second vertical section, a second horizontal section, a second opening and a second fixing node.

### BACKGROUND OF THE INVENTION

1. Field of the Invention

The present disclosure relates to a housing assembly; in particular, to a screw-less housing assembly for electronic devices, computer equipment and industrial equipment.

2. Description of Related Art

With advancements in internet communication, people rely more on internet technology, and new network communication equipment is continually being developed. The network switch is necessary equipment for communication between computers in a local area network.

Additionally, all types of computer equipment, electronic equipment and industrial equipment have a housing for protecting the sophisticated electronic components therein, so as to block interference from the outside environment and prevent inappropriate external forces from damaging the electronic components.

Conventional housings can have a two-piece design, wherein two units are assembled through engagement. For example, TW Patent Number 1285525 discloses a “Housing Structure Detachable by Hand”. However, the disclosure “Housing Structure Detachable by Hand” has a very complicated structure requiring production of a longitudinal groove, a guiding groove, a transverse sliding groove, a shaft, a guiding pin, and protruding edges. These parts are engaged and then fixed by a locking unit. The structure has a very complicated production process and a high production cost.

Hence, the present inventor believes the above mentioned disadvantages can be overcome, and through devoted research combined with application of theory, finally proposes the present disclosure which has a reasonable design and effectively improves upon the above mentioned disadvantages.

### SUMMARY OF THE INVENTION

The object of the present disclosure is to provide a housing assembly which can be disassembled, can be stably joined together, and has a simple structure and manufacturing process, so as to assist fast production and increase the good quality rate, effectively reducing production cost.

In order to achieve the aforementioned objects, the present disclosure provides a housing assembly including: a first housing having a top board and two side boards connected to the top board; a second housing having a bottom board; two first bolts respectively disposed at the two side boards proximal to one end thereof, wherein each of the two first bolts protrudes on an inner face of one of the two side boards; two second bolts respectively disposed at the two side boards proximal to the other end thereof, wherein each of the two second bolts protrudes on an inner face of one of the two side boards; two first guiding rails respectively formed on two sides of the bottom board of the second housing proximal to one end thereof, wherein the two first guiding rails each have a first guiding groove including a first vertical section and a first horizontal section, the bottom end of the first vertical section is formed with a first opening, the top end of the first vertical section is connected to one end of the first horizontal section, the other end of the first horizontal section is formed with a first fixing node; two second guiding rails respectively formed on two sides of the bottom board of the second housing proximal to the other end thereof, wherein the two second guiding rails each have a second guiding groove including a second vertical section and a second horizontal section, the top end of the second vertical section is formed with a second opening, the bottom end of the second vertical section is connected to one end of the second horizontal section, the other end of the second horizontal section is formed with a second fixing node; wherein the two first bolts respectively pass through the first openings of the two first guiding grooves, the two first vertical sections and the two first horizontal sections, such that the two first bolts move to the two first fixing nodes, and the two second bolts respectively pass through the second openings of the two second guiding grooves, the two second vertical sections and the two second horizontal sections, such that the two second bolts move to the two second fixing nodes, thereby joining the first housing and the second housing.

The present disclosure has the following advantages. The housing assembly of the present disclosure is screw-less. Two first bolts and two second bolts are disposed on the first housing, and two first guiding rails and two second guiding rails are formed on the second housing. The first bolts and the second bolts respectively engage the first guiding rails and the second guiding rails, such that the first housing and the second housing can mutually engage. The present disclosure is not limited to plastic components, can use metal components, can be disassembled and assembled multiple times, can be stably joined, have a simple structure and manufacturing process, can assist fast production and increase the good quality rate, and effectively lower production cost.

According to the present disclosure, the first bolts are inserted into the first guiding rails in the opposite direction to the second bolts which are inserted into the second guiding rails, and in conjunction with at least one flexible body, the first housing and the second housing drag each other and are joined together. Additionally, elastic clamps can be used on two sides to fix the first housing and the second housing to achieve the object of easy assembly.

The present disclosure can also use metal stamping to produce a protruding dome, to form a fixing structure for an electric circuit module (by a screw-less method), and in conjunction with a screw-less first housing and second housing, complete a structure of completely screw-less design.

In order to further the understanding regarding the present disclosure, the following embodiments are provided along with illustrations to facilitate the disclosure of the present disclosure.

### BRIEF DESCRIPTION OF THE DRAWINGS

FIG. 1 shows an exploded view of a housing assembly according to the present disclosure;

FIG. 2 shows a perspective view of a first housing according to the present disclosure;

FIG. 3 shows a perspective view of a second housing according to the present disclosure;

FIG. 4A to FIG. 4C show schematic diagrams of a first bolt moving in a first guiding rail according to the present disclosure;

FIG. 5A to FIG. 5C show schematic diagrams of a second bolt moving in a second guiding rail according to the present disclosure;

FIG. 6 shows a schematic diagram of an electric module assembled to a housing according to the present disclosure; and

FIG. 7 shows a perspective view of an assembled housing assembly according to the present disclosure.

### DETAILED DESCRIPTION OF THE PREFERRED EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings.

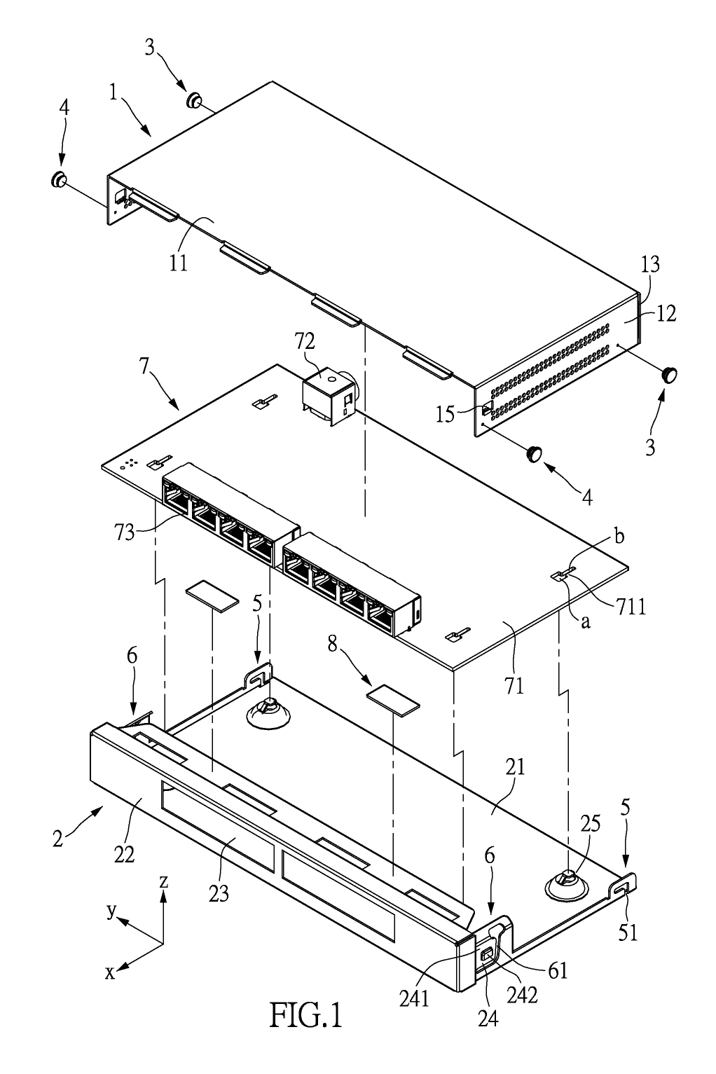

Referring to FIG. 1, the present disclosure provides a housing assembly applicable to electronic equipment, computer equipment, industrial equipment or other products. The present embodiment discloses a network switch, to serve as an example for description. However, the types of products which the housing assembly of the present disclosure is applicable to is not limited. The housing assembly includes a first housing 1, a second housing 2, two first bolts 3, two second bolts 4, two first guiding rails 5 and two second guiding rails 6.

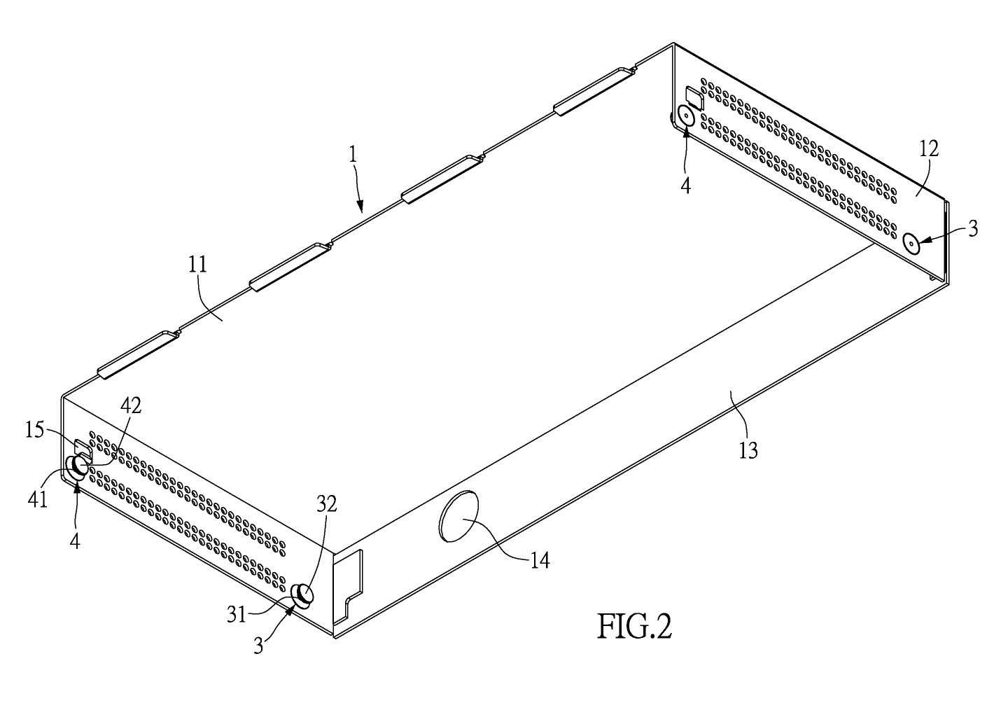

Referring to FIG. 1 and FIG. 2, the first housing 1 is preferably but not necessarily made of metal, and can be made of for example plastic. In the present embodiment the first housing 1 is substantially a cuboid. The first housing 1 can have a top board 11, two side boards 12 and a rear board 13. The two side boards 12 and the rear board 13 are connected to the top board 11. The two side boards 12 can extend downward from respectively two sides of the top board 11. The rear board 13 can extend downwards from the rear end of the top board 11, and two sides of the rear board 13 are respectively connected to the rear sides of the two side boards 12. The rear board 13 can be further formed with a first through hole 14, for exposing a corresponding connector from the first housing 1. However, the shape and structure of the first housing 1 is not limited thereto, and can be modified according to need. For example, the rear board 13 of the first housing 1 can be omitted, and a rear board can extend from the second housing 2 (not shown in the figures). The two side boards 12 of the first housing 1 can each be formed with a snap hole 15. The snap holes 15 can be respectively positioned proximal to the front ends of the side boards 12.

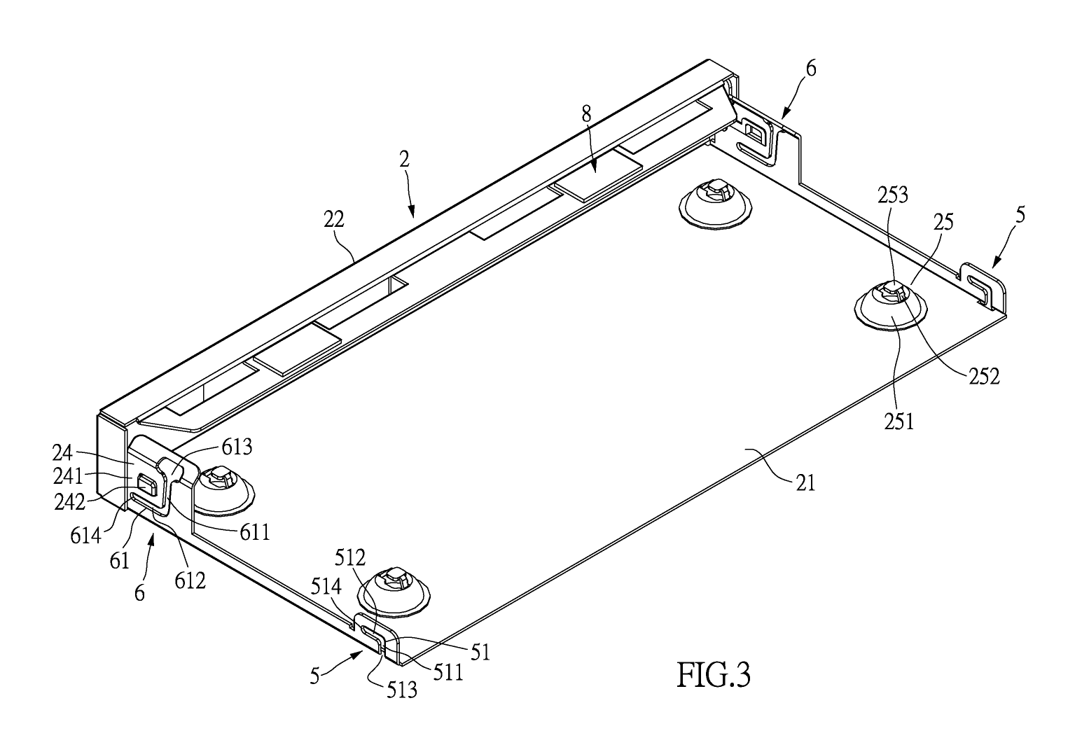

Referring to FIG. 1 and FIG. 3, the second housing 2 is preferably but not necessarily made of metal, and can be made of for example plastic. In the present embodiment the second housing 2 is substantially a cuboid. The second housing 2 can have a bottom board 21 and a front board 22. The front board 22 is connected to the bottom board 21. The rear board 22 can extend upwards from the bottom board 21. The front board 22 can be formed with second through holes 23, for exposing a corresponding connector from the second housing 2. However, the shape and structure of the second housing 2 is not limited thereto, and can be modified according to need. For example, the front board 22 of the second housing 2 can be omitted, and a front board can extend from the first housing 1 (not shown in the figures).

Two sides of the second housing 2 can each have an elastic snap 24. In the present embodiment the elastic snaps 24 are formed respectively on the second guiding rails 6. Each of the elastic snaps 24 has an elastic board 241, a snap body 242 is disposed on each of the elastic boards 241, and each of the snap bodies 242 selectively snaps into one of the snap holes 15. However, the elastic snaps 24 can also be replaced by other fastening mechanisms.

Referring to FIG. 1 and FIG. 2, the two first bolts 3 are preferably but not necessarily made of metal, and can be made of for example plastic. Referring to FIG. 2, the two first bolts 3 are respectively disposed at the two side boards 12 of the first housing 1 proximal to one end (e.g. the rear end) of the respective side board 12. The two first bolts 3 can be integrally formed as one body with the two side boards 12 of the first housing 1 respectively, or be joined onto the two side boards 12 of the first housing 1 respectively. In the present embodiment the two first bolts 3 are rivets. The two first bolts 3 are fixed respectively to the two side boards 12 of the first housing. The two first bolts 3 protrude respectively from the inner faces of the two side boards 12. The first bolts 3 can be cylindrical. The first bolts 3 can each have a first shaft portion 31 and a first head portion 32 connected to one end of the first shaft portion 31. The diameter of the first head portion 32 is greater than the diameter of the first shaft portion 31. However, the shape and structure of the first bolts 3 can be modified accordingly.

The two second bolts 4 are preferably but not necessarily made of metal, and can be made of for example plastic. The two second bolts 4 are respectively disposed at the two side boards 12 of the first housing 1 proximal to one end (e.g. the front end) of the respective side board 12. The two second bolts 4 can be integrally formed as one body with the two side boards 12 of the first housing 1 respectively, or be joined onto the two side boards 12 of the first housing 1 respectively. In the present embodiment the two second bolts 4 are rivets. The two second bolts 4 are fixed respectively to the two side boards 12 of the first housing 1. The two second bolts 4 protrude respectively from the inner faces of the two side boards 12. The second bolts 4 can be cylindrical. The second bolts 4 can each have a second shaft portion 41 and a second head portion 42 connected to one end of the second shaft portion 41. The diameter of the second head portion 42 is greater than the diameter of the second shaft portion 41. However, the shape and structure of the second bolts 4 can be modified accordingly.

Referring to FIG. 1 and FIG. 3, the two first guiding rails 5 are preferably but not necessarily made of metal, and can be made of for example plastic. The two first guiding rails 5 are respectively disposed on two sides of the bottom board 21 of the second housing 2 proximal to one end thereof (e.g. the rear end). The two first guiding rails 5 can extend upward from two sides of the bottom board 21 of the second housing 2, such that the two first guiding rails 5 are substantially perpendicular to the bottom board 21. Referring to FIG. 3, the first guiding rails 5 each have a first guiding groove 51. Each of the first guiding grooves 51 is substantially L-shaped, including a first vertical section 511 and a first horizontal section 512. The first vertical sections 511 extend along the vertical direction (the direction of the z-axis as shown in FIG. 1). The first horizontal sections 512 extend along the horizontal direction (the direction of the x-axis as shown in FIG. 1). The bottom end of the first vertical section 511 is formed with a first opening 513, the top end of the first vertical section 511 is connected to one end (e.g. the rear end) of the first horizontal section 512, the other end (e.g. the front end) of the first horizontal section 512 is formed with a first fixing node 514.

The two second guiding rails 6 are preferably but not necessarily made of metal, and can be made of for example plastic. The two second guiding rails 6 are respectively disposed on two sides of the bottom board 21 of the second housing 2 proximal to the other end thereof (e.g. the front end). The two second guiding rails 6 can extend upward from two sides of the bottom board 21 of the second housing 2, such that the two second guiding rails 6 are substantially perpendicular to the bottom board 21. The second guiding rails 6 each have a second guiding groove 61. Each of the second guiding grooves 61 is substantially L-shaped, including a second vertical section 611 and a second horizontal section 612. The second vertical sections 611 extend along the vertical direction (the direction of the z-axis as shown in FIG. 1). The second horizontal sections 612 extend along the horizontal direction (the direction of the x-axis as shown in FIG. 1). The top end of the second vertical section 611 is formed with a second opening 613, the bottom end of the second vertical section 611 is connected to one end (e.g. the rear end) of the second horizontal section 612, the other end (e.g. the front end) of the second horizontal section 612 is formed with a second fixing node 614. The second openings 613 of the second guiding grooves 61 are disposed at top ends, and the first openings 513 of the first guiding grooves 51 are disposed at the bottom ends, such that the second guiding grooves 61 and the first guiding grooves 51 are arranged to face opposite directions.

Referring to FIG. 1, the present disclosure can further include an electric circuit module 7. The electric circuit module 7 has a circuit board 71 having an appropriate electric circuit disposed thereon. The electric circuit can be modified according to the type of product being applied. The circuit board 71 has a first connector 72 and a plurality of second connectors 73 disposed thereon. The circuit board 71 is formed with a plurality of fixing holes 711. Each of the fixing holes 711 includes a first portion A and a second portion B in fluid communication with each other. The width of the first portion A (dimension in the direction of the y-axis) is greater than the width of the second portion B (dimension in the direction of the y-axis).

Referring to FIG. 1 and FIG. 3, a plurality of protruding domes 25 corresponding to the fixing holes 711 can be disposed on the bottom board 21 of the second housing 2. The protruding domes 25 can be formed by stamping the bottom board 21. Each of the protruding domes 25 has a protruding portion 251, two connection portions 252 and a pressing portion 253. The protruding portion 251 protrudes on the bottom board 21. The protruding portion 251 can be spherical or other shapes. The two connection portions 252 are elongated plates, and can be bent appropriately. The two connection portions 252 are connected to the protruding portion 251. For example, the lower ends of the two connecting portions 252 can be connected to the top portion of the protruding portion 251. The pressing portion 253 is preferably a flat plate but is not limited thereto. The shape of the pressing portion 253 can be square, circular, polygonal, etc. and is not limited thereto. The pressing portion 253 is connected to the two connection portions 252. For example, the pressing portion 253 can be connected to the upper ends of the two connection portions 252. The width of the pressing portion 253 (dimension in the direction of the y-axis) is greater than the width of the connection portions 252 (dimension in the direction of the y-axis). The width of the pressing portion 253 is smaller than the width of the width of the first portion A of the fixing hole 711.

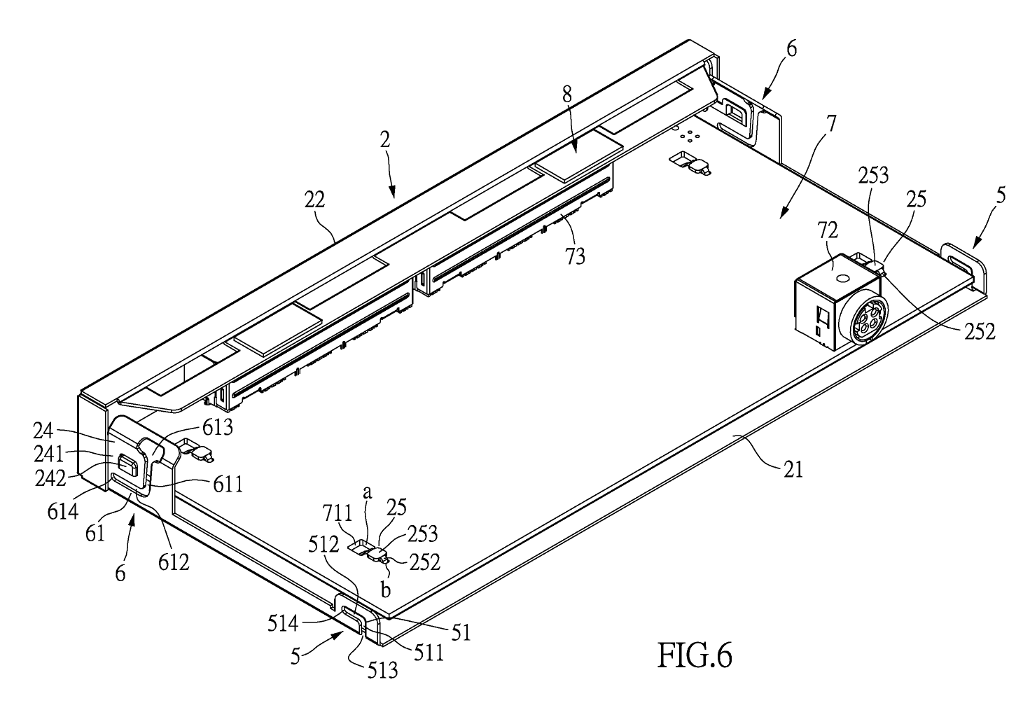

The electric circuit module 7 can be lowered (along the direction of the z-axis) onto the protruding portions 251 of the protruding domes 25, and make the pressing portions 253 pass upward through the first portions A of the fixing holes 711. Then, the electric circuit module 7 is pushed along a horizontal direction (the direction of the x-axis), such that the pressing portions 253 moves above the second portions B of the fixing holes 711, such that the pressing portions 253 protrudes over and presses the top face of the circuit board 71 (as shown in FIG. 6), such that the electric circuit module 7 cannot move in the direction of the z-axis (up and down) and a part of the connection portion 252 is fixed in the second portion B of the fixing hole 711 such that the electric circuit module 7 cannot move in the direction of the y-axis (left and right).

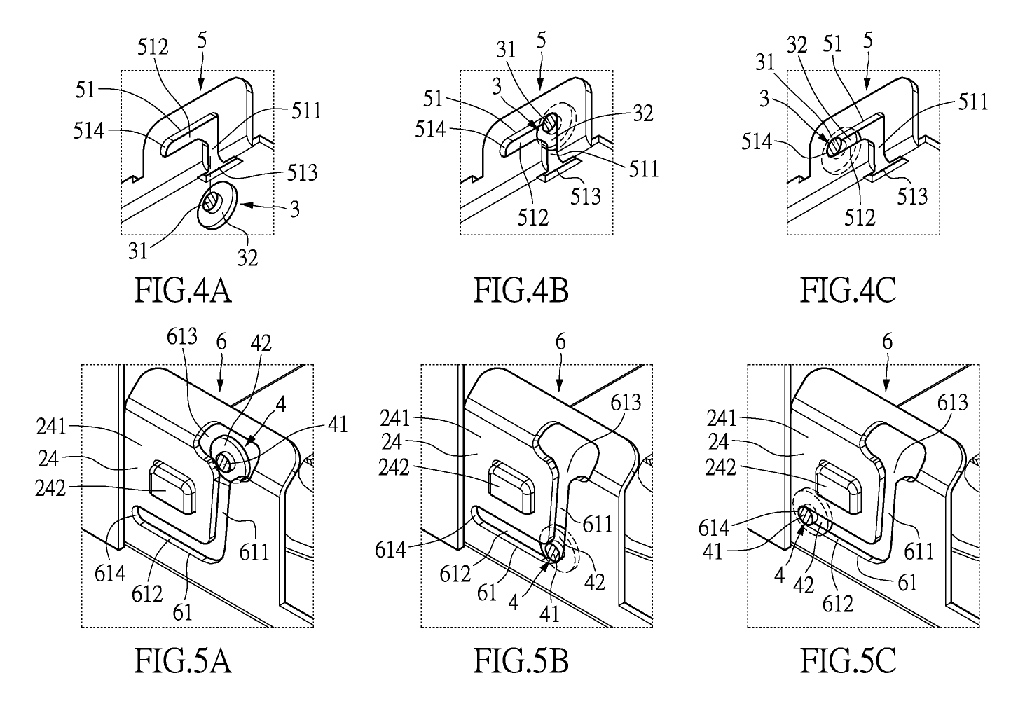

When the first housing 1 and the second housing 2 of the present disclosure are to be assembled, as shown in FIG. 4A and FIG. 4B, first, the two first bolts 3 protruding on the inner face of the inner boards 12 of the first housing 1 are passed through the first openings 513 of the two first guiding grooves 51 of the two first guiding rails 5 at two sides of the bottom board 21 of the second housing 2, and move upward to the first vertical sections 511. The first bolt 3 can pass through the first vertical section 511 and continue to move upward, such that the first bolt 3 temporarily stops at the junction between the first vertical section 511 and the first horizontal section 512. The first bolt 3 can act as a pivot at this location, such that the first housing 1 is pivotally connected to the second housing and the first housing 1 can pivot about the first bolts 3 to turn downward to cover the second housing (referring to FIG. 1, according to the location of the pivot, rotate about the y-axis).

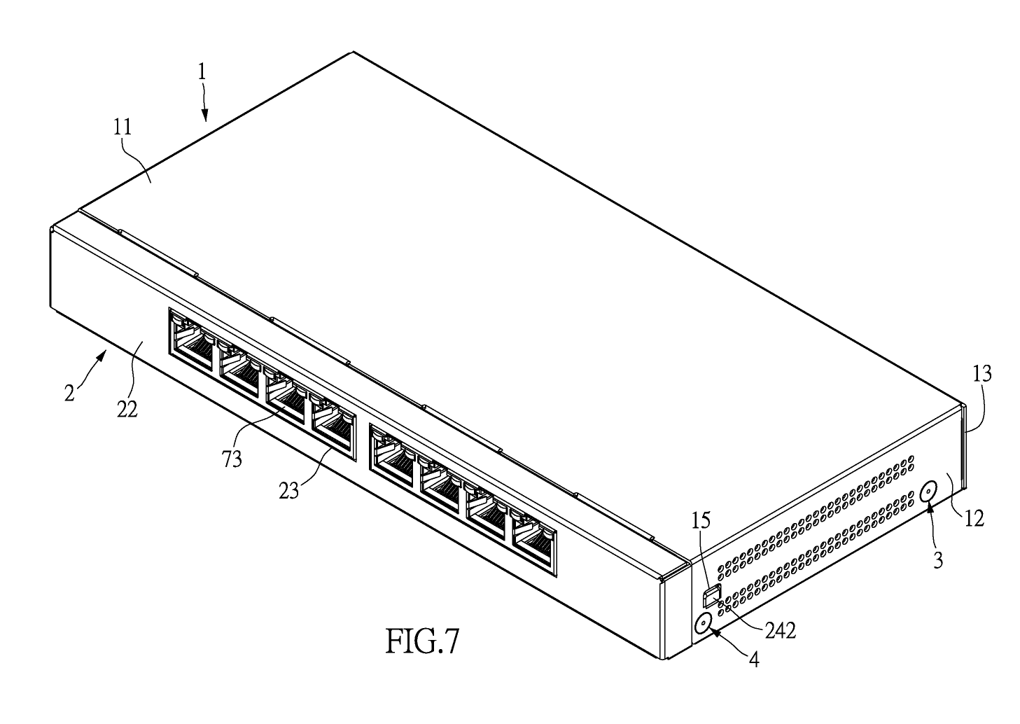

The first housing 1 rotates downward to cover the second housing according to the above description. As shown in FIG. 5A and FIG. 5B, the two second bolts 4 protruding on the inner face of the side boards 12 of the first housing 1 are passed through the second openings 613 of the two second guiding grooves 61 of the two second guiding rails 6 at two sides of the second board 21 of the second housing 2, and move downward to the second vertical sections 611. The second bolt 4 then pass through the second vertical section 611 and continues to move downward, such that the second bolt 4 temporarily stops at the junction between the second vertical section 611 and the second horizontal section 612. Referring to FIG. 4C and FIG. 5C, the first housing 1 is then pushed forward, such that the first bolt 3 passes through the first horizontal section 512 and moves to the first fixing node 514, and the second bolt 4 passes through the second horizontal section 612 and moves to the second fixing node 614, such that the first housing 1 and the second housing 2 are joined together (as shown in FIG. 7). The first connector 72 and the second connectors 73 are respectively aligned with the first through hole 14 and the second through holes 23, for plugging to other connectors.

At this moment, the snap bodies 242 of the elastic snaps 24 can snap into the two snap holes 15, such that the first housing 1 and the second housing 2 cannot move in the direction of the x-axis (forward and backward) with respect to each other. The two first bolts 3 and the two second bolts 4 are respectively fixed at the two first fixing nodes 514 and the two second fixing nodes 614, such that the first housing 1 and the second housing 2 cannot move in the direction of the z-axis (upward and downward) with respect to each other. The first head portions 32 of the two first bolts 3 abut the inner faces of the two first guiding rails 5, and the second head portions 42 of the two second bolts 4 abut the inner faces of the two second guiding rails 6, such that each of the two first guiding rails 5 is sandwiched between one of the two side boards 12 and the first head portion 32 of one of the two first bolts 3, each of the two second guiding rails 6 is sandwiched between one of the two side boards 12 and the second head portion 42 of one of the two second bolts 4, such that the housing 1 and the housing 2 cannot move in the direction of the y-axis (left and right) with respect to each other.

Additionally, the rear board 13 of the first housing 1 abuts one end (e.g. the rear end) of the circuit board 71, such that the electric circuit module 7 cannot move in the direction of the x-axis (forward and backward), such that the circuit board 71 is securely fixed on the protruding domes 25. When a user presses the two elastic snaps, the snap bodies 242 detach from the snap holes 25 such that the first housing 1 and the second housing 2 can be separated.

Additionally, the present disclosure can further include at least one flexible body 8. The flexible body 8 can be made of rubber or sponge. The flexible body 8 can be rectangular or other shapes. The flexible body 8 is disposed between the bottom face of the front end of the top board 11 of the first housing 1 and the upper face of the front board 22 of the second housing 2. The elasticity of the flexible body 8 can be utilized to abut between the top board 11 of the first housing 1 and the front board 22 of the second housing, so as to eliminate the gap between the first housing 1 and the second housing 2, such that the first housing 1 and the second housing 2 are tightly sealed therebetween and an upward elastic force is provided to the first housing 1, such that when the first housing 1 and the second housing 2 are to be separated, the first housing 1 can automatically spring upward to be retrieved.

The present disclosure has the following advantages. The housing assembly of the present disclosure is screw-less. Two first bolts and two second bolts are disposed on the first housing, and two first guiding rails and two second guiding rails are disposed on the second housing. Then, using the engagements between the first bolts and the first guiding rails, and the engagements between the second bolts and the second guiding rails, the first housing and the second housing become mutually cooperating components. The present disclosure is not limited to plastic units and can use metal units, can be assembled and disassembled multiple times, can be stably joined, has a simple structure and manufacturing process, can assist fast production and increase the good quality rate, and effectively lower production cost.

The first bolts are inserted into the first guiding rails in the opposite direction in which the second bolts are inserted into the second guiding rails. In conjunction with at least one flexible body, the first housing and the second housing drag each other and are joined together. Additionally, two elastic snaps fix the first housing and the second housing, achieving the object of simple assembly.

The present disclosure can use metal stamping to produce protruding domes, to form (screw-less) fixing structures for the electric circuit module. In conjunction with the screw-less design of the first housing and the second housing, a completely screw-less design is completed.

The present disclosure achieves a new design which is completely screw-less. Bolts (rivet units) work in conjunction with guiding rails. At least one flexible body is assembled to form a tightly sealed screw-less structure which can be assembled and disassembled multiple times without being damaged.

The descriptions illustrated supra set forth simply the preferred embodiments of the present disclosure; however, the characteristics of the present disclosure are by no means restricted thereto. All changes, alternations, or modifications conveniently considered by those skilled in the art are deemed to be encompassed within the scope of the present disclosure delineated by the following claims.

What is claimed is:

1. A housing assembly comprising:
a first housing, having a top board and two side boards connected to the top board;
a second housing, having a bottom board;
two first bolts, respectively disposed at the two side boards of the first housing, wherein each of the first bolts is arranged proximal to one end of one of the two side boards, and each of the first bolts protrudes on an inner face of one of the two side boards;
two second bolts, respectively disposed at the two side boards of the first housing, wherein each of the second bolts is arranged proximal to another end of one of the two side boards, and each of the second bolts protrudes on an inner face of one of the two side boards;
two first guiding rails, respectively disposed at two sides of the bottom board of the second housing, wherein each of the first guiding rails is arranged proximal to one end of one of the sides of the bottom board, each of the two first guiding rails has a first guiding groove, each of the first guiding grooves includes a first vertical section and a first horizontal section, the lower end of each of the first vertical sections is formed with a first opening, the upper end of each of the first vertical sections is connected to one end of the respective first horizontal section, and the other end of each of the first horizontal sections is formed with a first fixing node;
two second guiding rails, respectively disposed at two sides of the bottom board of the second housing, wherein each of the second guiding rails is arranged proximal to another end of one of the sides of the bottom board, each of the two second guiding rails has a second guiding groove, each of the second guiding grooves includes a second vertical section and a second horizontal section, the upper end of each of the second vertical sections is formed with a second opening, the lower end of each of the second vertical sections is connected to one end of the respective second horizontal section, and the other end of each of the second horizontal sections is formed with a second fixing node;
wherein the two first bolts respectively pass through the first openings, the first vertical sections, and the first horizontal sections of the two first guiding grooves, the two second bolts respectively pass through the second openings, the second vertical sections, and the second horizontal sections of the two second guiding grooves, so that the two first bolts respectively move to the two first fixing nodes, the two second bolts respectively move to the two second fixing nodes, and the first housing and the second housing are joined together.

2. The housing assembly according to claim 1, wherein the two side boards of the first housing are each formed with a snap hole, the two sides of the second housing each have an elastic snap, the elastic snaps each have an elastic board, a snap body is disposed on each of the elastic boards, and the snap bodies selectively respectively snaps into the snap holes.

3. The housing assembly according to claim 1, wherein the two first bolts each have a first shaft portion and a first head portion connected to one end of the first shaft portion, and the two second bolts each have a second shaft portion and a second head portion connected to one end of the second shaft portion.

4. The housing assembly according to claim 3, wherein the first head portions of the two first bolts respectively abut inner faces of the two first guiding rails, the second head portions of the two second bolts respectively abut inner faces of the two second guiding rails, so that each of the two first guiding rails is sandwiched between one of the two side boards and the first head portion of one of the two first bolts, and each of the two second guiding rails is sandwiched between one of the two side boards and the second head portion of one of the two second bolts.

5. The housing assembly according to claim 1, wherein the two first guiding rails extend upward respectively from two sides of the bottom board of the second housing, and the two first guiding rails are substantially perpendicular to the bottom board.

6. The housing assembly according to claim 1, wherein the two second guiding rails extend upward respectively from two sides of the bottom board of the second housing, and the two second guiding rails are substantially perpendicular to the bottom board.

7. The housing assembly according to claim 1, further comprising an electric circuit module having a circuit board, wherein the circuit board has a plurality of fixing holes, each of the fixing holes include a first portion and a second portion in fluid communication with each other, the bottom board of the second housing has a plurality of protruding domes disposed thereon, each of the protruding domes has a protruding portion, a connection portion and a pressing portion, the protruding portion protrudes from the bottom board, the connection portion is connected to the protruding portion, the pressing portion is connected to the connection portion, the electric circuit module is disposed on the protruding portions of the protruding domes, the pressing portions pass through the first portions of the fixing holes, the pressing portions move above the second portions of the fixing holes, and the pressing portions press the top face of the circuit board.

8. The housing assembly according to claim 7, wherein the first housing has a rear board, and the rear board of the first housing abuts one end of the circuit board.

9. The housing assembly according to claim 1, further comprising at least one flexible body, the second housing further includes a front board, the flexible body is disposed between the bottom face of the front end of the top board of the first housing and the upper face of the front board of the second housing.
